(19) United States
(12) Patent Application Publication
(10) Pub. No.: US 2026/0171151 A1
(43) Pub. Date: Jun. 18, 2026

(54) RESISTIVE RANDOM-ACCESS MEMORY WITH HYBRID BONDING INTEGRATION

(71) Applicant: HEFEI RELIANCE MEMORY LIMITED, Hefei (CN)

(72) Inventors: Chao-Yang CHEN, Hefei (CN); Zhichao Lu, San Jose, CA (US); Liang Zhao, Sunnyvale, CA (US)

(21) Appl. No.: 19/084,478

(22) Filed: Mar. 19, 2025

Related U.S. Application Data
(63) Continuation of application No. PCT/CN2024/139909, filed on Dec. 17, 2024.

(51) Int. Cl. G11C 13/00; H01L 23/00; H01L 25/18

(52) U.S. Cl. CPC G11C 13/0069; G11C 13/0026; G11C 13/004; H10W 90/00; G11C 2013/0054; H10W 90/20; H10W 90/791

(57) ABSTRACT

The embodiments of the present application provide a memory device and a method for preforming a write operation in a memory device. The memory device comprising: a memory chip comprising a plurality of memory cells made at a first process node; and a control chip comprising a control circuit made at a second process node, wherein the first process node is more advanced than the second process node; wherein the control chip and the memory chip are bonded together to form the memory device, and the control circuit is configured to control an operation of the plurality of the memory cells in the memory chip.

### CROSS-REFERENCE TO RELATED APPLICATION

This application is a continuation application of International Patent Application No. PCT/CN 2024/139909, filed on Dec. 17, 2024, and entitled “Resistive Random-Access Memory with Hybrid Bonding Integration”. The above-referenced application is incorporated herein by reference in its entirety.

### TECHNICAL FIELD

The present invention relates generally to a method to fabricate a novel resistive random-access memory chip, and more specifically to fabricate resistive random-access memory chip with heterogeneous integration.

### BACKGROUND

Resistive Random Access Memory (RRAM) is a type of non-volatile memory where the device's resistance can be switched between a low resistance state (LRS) and a high resistance state (HRS) by applying the appropriate voltage. The difference in resistance between LRS and HRS is used to store digital data as “0” and “1.”

In a typical RRAM memory IC, various peripheral circuits are formed alongside the RRAM array, and the same process node is used to manufacture both the memory array and the peripheral circuits. However, this approach is not optimal, as only the memory array requires the most advanced process technology to achieve high density, while the peripheral circuits could be manufactured with a more mature (lower cost) process node.

### SUMMARY

To address the issue identified above, a two-chip solution with heterogeneous integration is provided in accordance with the embodiments of the present invention.

According to a first aspect of the present invention, a memory device is provided, including: a memory chip including a plurality of memory cells made at a first process node; and a control chip including a control circuit made at a second, wherein the first process node is more advanced than the second process node; wherein the control chip and the memory chip are bonded together to form the memory device via hybrid bonding integration technique, and the control circuit is configured to control an operation of the plurality of the memory cells in the memory chip.

In another embodiment of the present invention, the control circuit further includes a multiplexer configured to control a source line or a bit line for a memory cell.

In another embodiment of the present invention, the memory chip does not include a multiplexer configured to control a source line or a bit line for a memory cell.

In another embodiment of the present invention, the control circuit further includes a decoder configured to control a word line for a memory cell.

In another embodiment of the present invention, the memory chip does not include a decoder configured to control a word line for a memory cell.

In another embodiment of the present invention, the control circuit further includes a sense amplifier configured to amplify a signal for from a memory cell.

In another embodiment of the present invention, the control circuit further includes a charge pump configured to charge generate voltage required to program a memory cell.

In another embodiment of the present invention, the control chip further includes a processor.

In another embodiment of the present invention, the control chip further includes an analog circuit.

In another embodiment of the present invention, the control chip further includes a transmitter.

In another embodiment of the present invention, the control chip further includes a sensor.

In another embodiment of the present invention, a gate length of a transistor in the memory chip is smaller than a gate length of a transistor in the control chip.

In another embodiment of the present invention, the memory chip includes only one type of transistors, and the control chip includes a plurality type of transistors.

In another embodiment of the present invention, the memory chip includes only NMOS transistors.

In another embodiment of the present invention, the memory chip includes only PMOS transistors.

In another embodiment of the present invention, each memory cell includes a memory element formed above a substrate.

In another embodiment of the present invention, the memory element is selected from a group consisting of a Resistive Random Access Memory (RRAM); a Conductive-Bridge Random Access Memory (CBRAM); a Magnetic Random Access Memory (MRAM); a Ferroelectric Random Access Memory (FeRAM); and a Phase Change Random Access Memory (PCRAM).

In another embodiment of the present invention, each memory cell includes a resistive memory element formed above a substrate.

In another embodiment of the present invention, the memory cell includes: an access transistor formed on the substrate; a contact; a first metal layer; a bottom electrode; the resistive memory element; a first via; and a second metal layer; wherein the contact is disposed between a terminal of the access transistor and the first metal layer, the bottom electrode is disposed between the first metal layer and the resistive memory element, the first via is disposed between the resistive memory element and the second metal layer.

In another embodiment of the present invention, a top surface of the memory chip includes a plurality of first conductive pads and a first insulating region, a top surface of the control chip includes a plurality of second conductive pads and a second insulating region.

In another embodiment of the present invention, a first conductive pad is bonded to a second conductive pad, and the first insulating region is bonded to the second insulating region.

In another embodiment of the present invention, the plurality of first conductive pads are connected to a second metal layer in the memory chip by a plurality of memory chip vias, and a plurality of second conductive pads are connected to a second metal layer in the control chip by a plurality of control chip vias, wherein the plurality of memory chip vias include a same length.

In another embodiment of the present invention, prior to performing a write operation to a memory cell, the control circuit is configured to perform a read operation on the memory cell.

In another embodiment of the present invention, prior to performing a write operation to a memory cell, the control circuit is configured to compare data to be written with a result of a read operation.

In another embodiment of the present invention, the control circuit is configured to perform the write operation only if the data to be written does not match the result of the read operation.

According to a second aspect of the present invention, a method for performing a write operation in a memory device is provided, wherein the memory device includes a memory chip including a plurality of memory cells made at a first process node; and a control chip including a control circuit made at a second, wherein the first process node is more advanced than the second process node; wherein the control chip and the memory chip are bonded together to form the memory device, and the control circuit is configured to control an operation of the plurality of the memory cells in the memory chip; the method including: receiving an address of a memory cell in the memory chip and data to be written to the memory cell; by the control chip; performing a read operation on the memory cell; and performing a write operation on the memory cell after the read operation.

In another embodiment of the present invention, the method further including comparing the data to be written with a result of the read operation before performing the write operation on the memory cell.

In another embodiment of the present invention, performing a write operation on the memory cell after the read operation including performing a writing operation on the memory cell after the read operation only if the data to be written does not match the result of the read operation.

In the present invention, the memory chip is fabricated using an advanced process node, while the control chip is processed with a mature node. These two chips are then combined using 3D integration techniques, such as hybrid bonding, to form a fully functional memory chip.

In accordance with embodiments of the present invention, only the memory cells are fabricated using an advanced process node, while the peripheral circuits are fabricated using a mature node, which substantially reduces the cost of the memory chip, while increases the density of the memory cells.

### BRIEF DESCRIPTION OF THE DRAWINGS

The embodiments of the present invention may be more readily understood by referring to the following drawings.

FIG. 1A is a schematic diagram illustrating a memory device architecture commonly used in the industry.

FIG. 1B is a schematic diagram illustrating a novel memory device architecture with a hybrid bonding structure in accordance with embodiments of the present invention.

FIG. 2A is a schematic diagram illustrating a memory chip architecture within a hybrid bonding structure memory device commonly used in the industry.

FIG. 2B is a schematic diagram illustrating a novel Mux-free memory chip architecture in accordance with embodiments of the present invention.

FIG. 3 is a schematic diagram illustrating a novel customer defined memory device architecture with a hybrid bonding structure in accordance with embodiments of the present invention.

FIG. 4 is a schematic diagram illustrating a novel memory device architecture with a hybrid bonding structure in accordance with embodiments of the present invention.

FIG. 5A-FIG. 5B are schematic diagrams illustrating thickness and material of RRAM stack layers in the novel process for embedded RRAM in accordance with embodiments of the present invention.

FIG. 6 illustrates an example process flow for performing a write operation in a memory device in accordance with embodiments of the present invention.

### DETAIL DESCRIPTION OF THE EMBODIMENTS

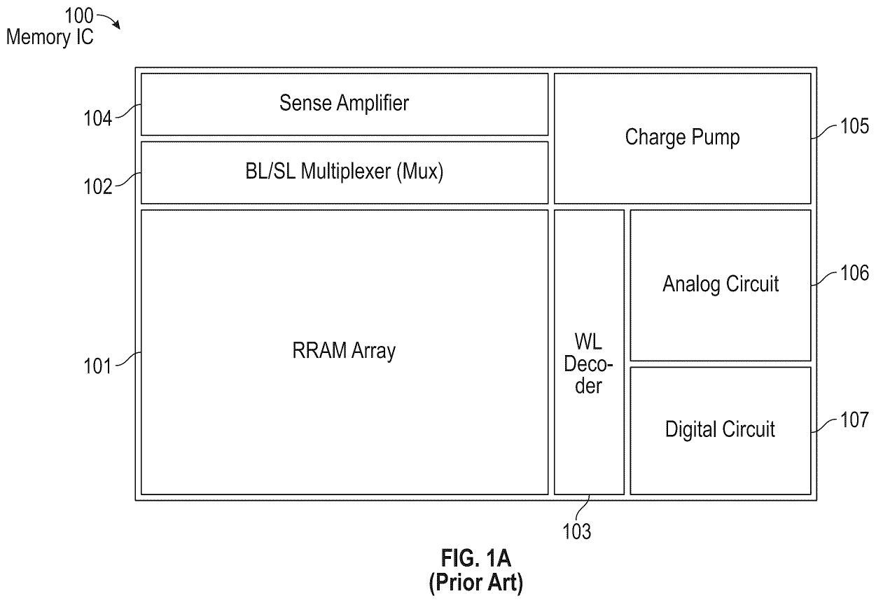

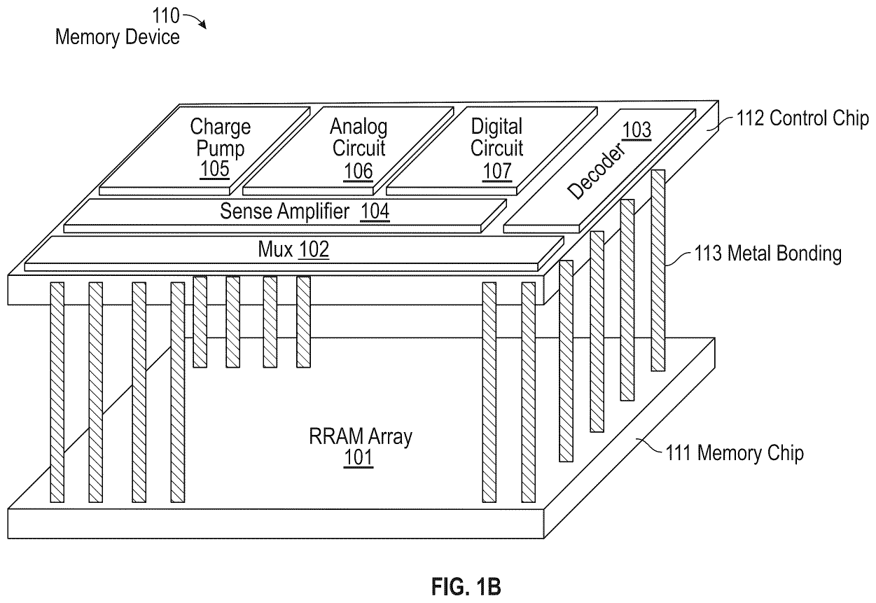

In a typical RRAM memory IC, beside the RRAM array, many peripheral circuits are required to support the functionality of RRAM. As show in FIG. 1A, a typical RRAM memory IC 100 may include a RRAM array 101, a bit line (BL)/source line (SL) multiplexer (Mux) 102, a word line (WL) decoder 103, a sense amplifier 104, a charge pump 105, an analog circuit 106, and a digital circuit 107. Thus, a lot of valuable areas are used to make the peripheral circuits, which limits the wafer areas that can be used to make RRAM memory cells. Furthermore, the most advanced process is required to make the memory cells to achieve high density, while the peripheral circuits can be processed with mature node, but it is not feasible to use different process node on the same wafer. (b) In the present invention, two chips solution is proposed. RRAM array is fabricated with advanced node while other circuits are processed with mature node. These two chips are then combined with hybrid bonding technique. With this approach, the area on advanced process node wafer can be fully dedicated to fabricate high density memory cell, which would increase the competitiveness of the memory device. In addition, the advanced proceed used to fabricate high density memory cell can be further simplified when only one type of transistor with its regular and repetitive patterns is need to be fabricated, which in the end would significantly reduce process defects and increase chip yield.

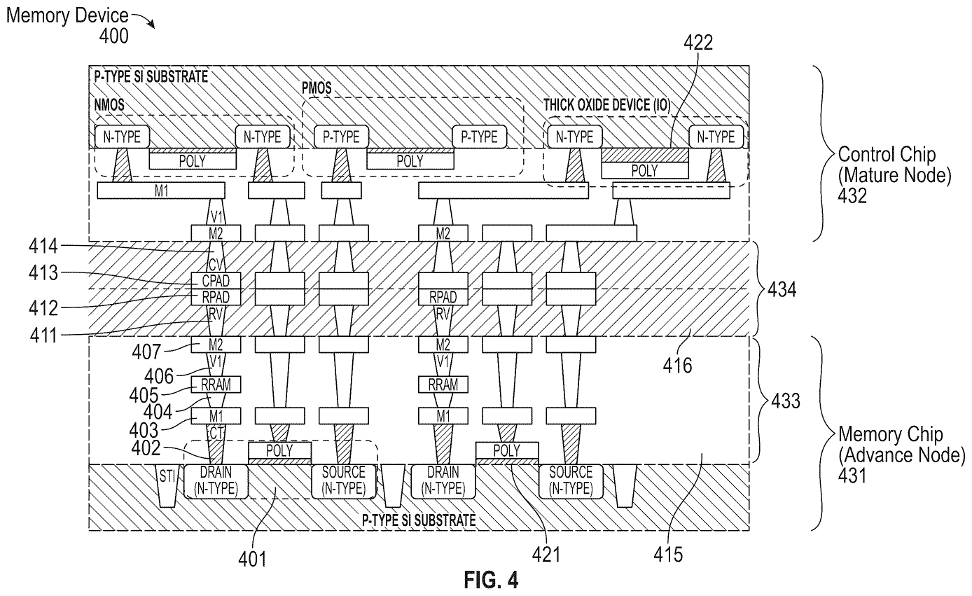

In the present invention, as shown in FIG. 1B, two chips solution is proposed. RRAM array is fabricated with advanced node while other circuits are processed with mature node. The memory device 110 may include a memory chip 111 and a control chip 112. The memory chip 111 includes a plurality of memory cells (denoted as “RRAM Array 101” in FIG. 1B) made at first process mode. The control chip 112 includes a control circuit made at a second process node, where the first process node is more advanced than the second process node. These two chips are bonded together with “hybrid bonding” technique (denoted as “Hybrid Bonding 113” in FIG. 1B) to form the memory device 110, and the control circuit is configured to control an operation of the plurality of the memory cells in the memory chip 111. The hybrid bonding, as will be elaborated later in descriptions of FIG. 4, comprises metal bonding and insulation bonding. FIG. 1B illustrates the metal bonding 113 but does not show the insulation bonding for the sake of visual clarity, which is also part of the structure.

Since the wafer used to create the memory chip 111 contains only memory cells and no control circuits, a higher number of memory cells can be fabricated on the same wafer. Thus, the utilization of the wafer is optimized.

As shown in FIG. 1B, the control chip 112 includes a Multiplexer (Mux) 102, a decoder 103, a sense amplifier 104, a charge pump 105, an analog circuit 106 and a digital circuit 107. The Mux 102 in the control chip 112 is configured to control a source line or a bit line for a memory cell in RRAM array 101, whereas the memory chip 111 does not include a multiplexer configured to control a source line or a bit line for a memory cell in RRAM array 101. The decoder 103 in the control chip 112 is configured to control a word line for a memory cell in RRAM array 101, whereas the memory chip 111 does not include a decoder configured to control a word line for a memory cell in RRAM array 101. The sense amplifier 104 in the control chip 112 is configured to amplify a signal from a memory cell in RRAM array 101, whereas the memory chip 111 does not include a sense amplifier configured to amplify a signal from a memory cell in RRAM array 101. The charge pump 105 in the control chip 112 is configured to generate voltage required to program a memory cell in RRAM array 101, whereas the memory chip 111 does not include a charge pump configured to generate voltage required to program a memory cell in RRAM array 101. Furthermore, the memory chip 111 does not include an analog circuit 106 or a digital circuit 107.

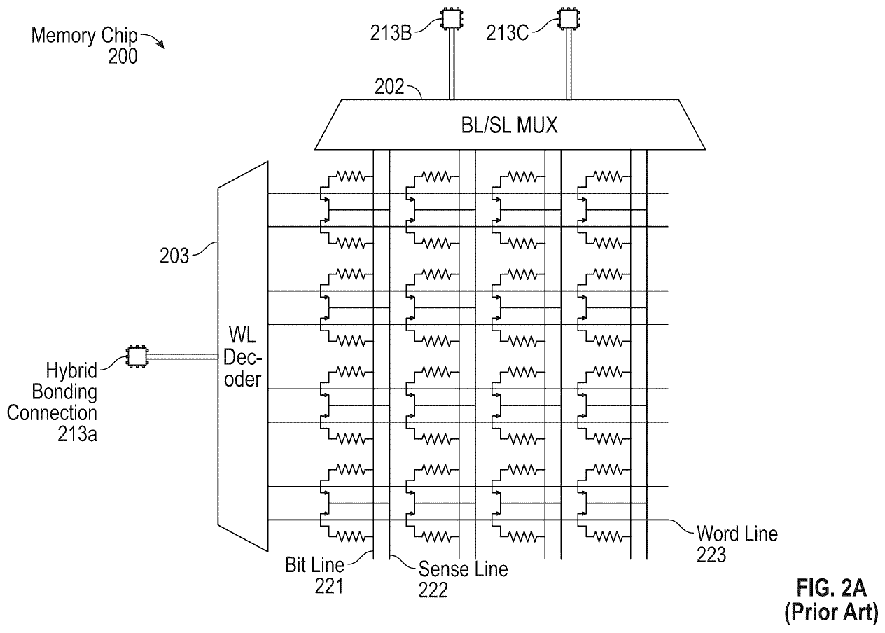

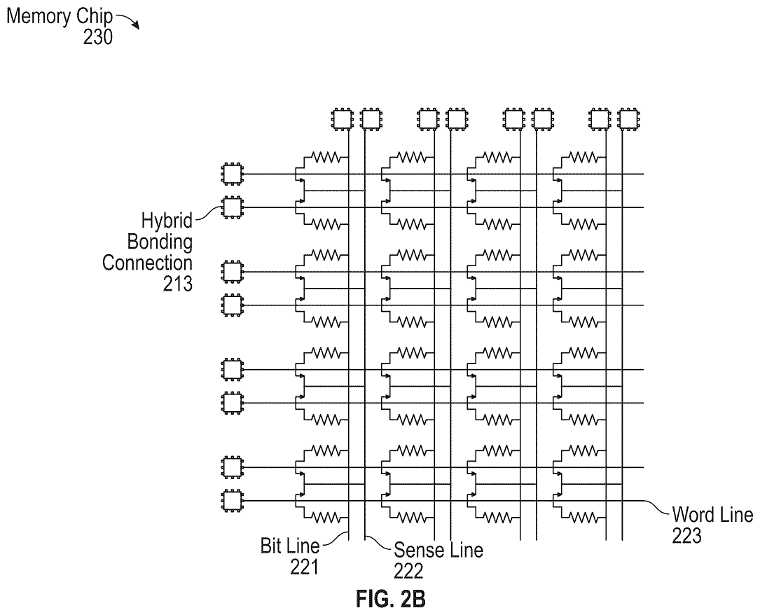

As shown in FIG. 2A, prior art with hybrid bonding structure has bit line (BL)/source line (SL) mux 202 and word line (WL) decoder 203 on a memory chip 200 and has hybrid bonding connection 213a, 213b and 213c after BL/SL Mux 202 or WL decoder 203. Whereas memory chip 230 of the present invention may be Mux-free, as shown in FIG. 2B, since it only includes one type of transistor (either nmos or pmos) on RRAM chip. The hybrid bonding connections 213 connect to individual word lines 223, Bit Lines 221 and Source Lines 222 directly.

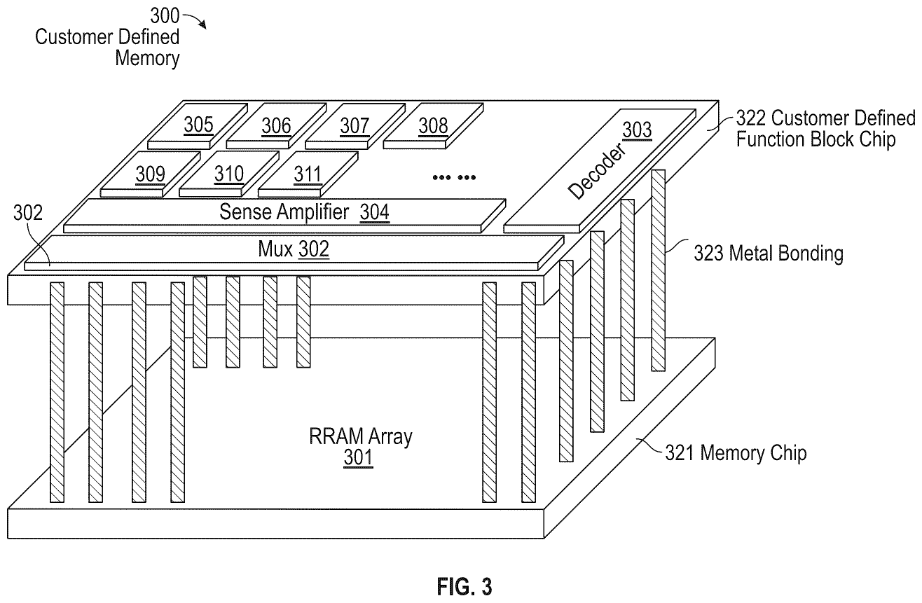

FIG. 3 shows a schematic diagram of a customer defined memory (CDM) 300, which may include a memory chip 321 and a customer defined function block chip 322 connected by hybrid bonding (for a better readability, FIG. 3 illustrates the metal bonding 323, but does not show the insulation bonding, which is also part of the hybrid bonding structure). The customer defined function block chip 322 may includes a Mux 302, a decoder 303, a sense amplifier 304, a MCU 305, an analog circuit 306, a digital circuit 307, an ECC memory 308, a passive device 309, a sensor 310, a transmitter 311, and other customer defined blocks. The other customer defined function blocks may include other memory (e.g., SRAM), a power management IC, a mixed signal interface and an RF component. The analog circuit 306 may includes an ADC, a DAC, a PLL, a V/I reference DC/DC, a power supply, or other analog circuits. The digital circuit 307 may includes an MCU, a NPU, a GPU, a CPU or other digital circuits. The passive device 309 may include an inductor, a capacitor, a resistor, or other passive devices. The sensor 310 may include an image sensor, a CCD, a temperature sensor, a pressure sensor, a gas sensor, or other sensors. The mixed signal interface may include PCIe, Serdes, DDR, CXL, SPI/QPI, or other mixed signal interfaces. The RF component may include LNA, VCO, mixer and other RF components. The transmitter 311 may transmit communication signals. The memory chip 321 may includes high density, high bandwidth and low power memory. In some embodiments, the memory chip 321 may includes simple memory cell only.

The CDM 300 offers a comprehensive solution in the non-volatile memory (NVM) and non-volatile static random-access memory (NVSRAM) space. It is the most cost-effective option with a density range from approximately Mbit to multi-Gbit, featuring finer memory capacity granularity.

In addition to integrating customer-defined functional blocks, the CDM 300 delivers greater value within the same cost envelope. This flexibility allows for tailored, cost-effective solutions that meet specific customer requests while lowering the entry barriers for the adoption of RRAM and other emerging memory technologies, because only the control chip need to be taped out utilizing low-cost mature process while the advanced node memory chip can be re-used.

The CDM 300 extends its capabilities with multi-layer 3D integration for higher density memory and 2.5D interposer technology that provides high bandwidth. It is compatible with advanced memory interfaces, including SPI/QPI, DDR 5, CXL, PCIe 6.0, and 112G SerDes.

Furthermore, the CDM 300 achieves SRAM-compatible speeds with random access, making it suitable for AI workloads in both edge and datacenter environments, enhancing performance while reducing power consumption.

The customer-defined memory CDM 300 in the present invention enhances device versatility by allowing customers to select specific features tailored to their needs. This approach enables memory to incorporate various control functionalities, allowing control circuits to be integrated directly with the memory cells, providing a more adaptable and feature-rich solution.

As shown in FIG. 4, memory devise 400 includes a memory chip 431 and a control chip 432. The memory chip 431 uses more advanced nodes than the control chip 432. The memory chip 431 includes a plurality of memory cells. The memory chip 431 only includes one type of transistor 410, which may either be nmos or pmos. On the other hand, the control chip 432 may contain many different types of transistors, which may be nmos, pmos, IO transistor, etc.

Since the memory chip 431 uses more advanced nodes than the control chip 432, the gate length 421 of access transistors 401 in the memory chip 431 is smaller than the gate length 422 of all the transistors in the control chip 432:

L_{Gate_Memory}<L_{Gate_Control}.

The present invention uses only one type of transistor within the memory chip 431, significantly simplifying the fabrication process. By reducing the need for multiple types of transistors, this approach lowers the technical complexity, reduces number of photomasks, and minimizes the number of manufacturing steps required. This streamlined process not only decreases production difficulty but also enhances yield rates and reliability, ultimately leading to a reduction in overall manufacturing costs.

The memory chip 431 includes a p-type Si substrate, a BEOL metal and dielectric layer 433 and a hybrid bonding metal and dielectric layer 434. The p-type Si substrate includes the access transistor 401. The BEOL metal and dielectric layer 433 includes a contact 402, a first metal layer 403, a bottom electrode 404, a resistive memory element 405, a first via 406, a second metal layer 407 and insulation 415, wherein the contact 402 is disposed between a terminal of the access transistor 401 and the first metal layer 403, the bottom electrode 404 is disposed between the first metal layer 403 and the resistive memory element 405, the first via 406 is disposed between the resistive memory element 405 and the second metal layer 407. The BEOL metal and dielectric layer and its components, including the resistive memory element 405, are formed above the substrate.

The resistive memory element 405 is in BEOL of the memory chip 431.

The resistive memory element 405 may be a Resistive Random Access Memory (RRAM), a Conductive-Bridge Random Access Memory (CBRAM), a Magnetic Random Access Memory (MRAM), a Ferroelectric Random Access Memory (FeRAM), or a Phase Change Random Access Memory (PCRAM).

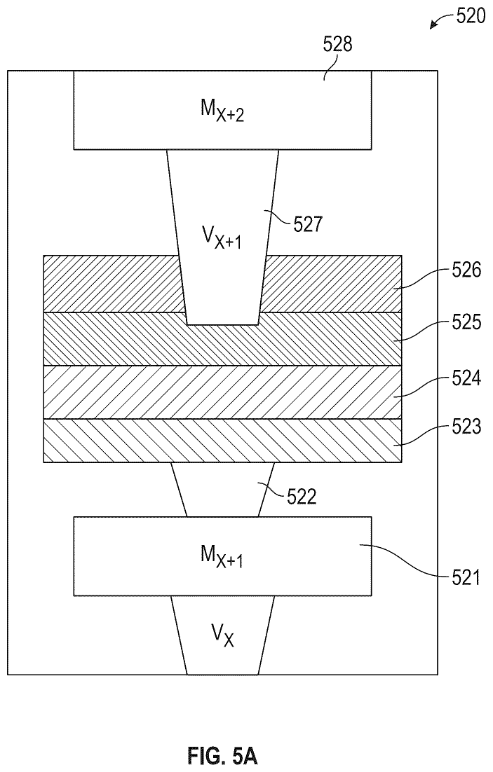

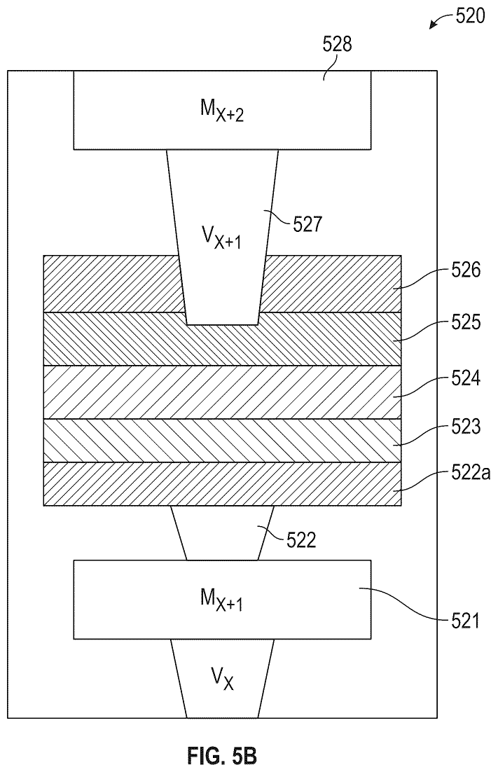

The resistive memory element 405 may have two types of RRAM stack in the RRAM region 520: (a) RRAM with only one BE material, as shown in FIG. 5A; and (b) RRAM with two bottom electrodes, as shown in FIG. 5B. Referring to FIG. 5A, the thickness of the RRAM BE 522 may be 5 nm-500 nm and the material of the RRAM BE 522 may be metals (Ti, Hf, Ta, Ru, Ir, Pt, etc.), metal oxide (TiOx, TaOx, HfOx, etc.), metal nitrides (TiN, TaN, AlN, etc.), metal oxynitride (TiON, TaON, AlON, etc.), or other suitable conductive materials. The thickness of the dielectric layer 523 may be 0.1 nm-50 nm and the material of the dielectric layer 523 may be dielectric (SiO2, Ta2O5, TiO2, ZrO2, HfO2, Al2O3, etc.), including mixture and/or combination of these materials. The thickness of the capping layer 524 may be 1 nm-500 nm and the material of the capping layer 524 may be metals (Ti, Hf, Ta, Ru, Ir, Pt, etc.), metal oxide (TiOx, TaOx, HfOx, etc.), metal nitrides (TiN, TaN, AlN, etc.), metal oxynitride (TiON, TaON, AlON, etc.), or other suitable conductive materials. The thickness of the top electrode 525 may be 1 nm-500 nm and the material of the top electrode 525 may be metals (Ti, Hf, Ta, Ru, Ir, Pt, etc.), metal oxide (TiOx, TaOx, HfOx, etc.), metal nitrides (TiN, TaN, AlN, etc.), metal oxynitride (TiON, TaON, AlON, etc.), or other suitable conductive materials. On top of the RRAM stack, a hard mask layer 526 is also deposited. The material of the hard mask layer 526 may be SiN. In this example, via Vₓ₊₁ 527 and metal layer Mₓ₊₂ 528 is used where via Vₓ₊₁ 527 is etched through the hard mask 526 and connects to the RRAM top electrode 525.

Referring to FIG. 5B, there is a second RRAM BE 522a deposited between the dielectric layer 523 and the first RRAM BE 522. The thickness of the second RRAM BE 522a may be 1 nm-500 nm and the material of the second RRAM BE 522a may be metals (Ti, Hf, Ta, Ru, Ir, Pt, etc.), metal oxide (TiOx, TaOx, HfOx, etc.), metal nitrides (TiN, TaN, AlN, etc.), metal oxynitride (TiON, TaON, AlON, etc.), or other suitable conductive materials.

As shown in FIG. 4, the memory chip portion of the hybrid bonding metal and dielectric layer 434 includes memory chip vias 411, memory chip pads 412 and insulation 416; the control chip portion of the hybrid bonding metal and dielectric layer 434 includes control chip vias 414, control chip pads 413 and insulation 416. A top surface of a memory chip 431 includes a plurality of first conductive pads, which are the memory chip pads 412, and a first insulation region; a top surface of a control chip 432 includes a plurality of second conductive pads, which are the control chip pads 413, and a second insulation region. In a hybrid bonding process, the memory chip pads 412 are bonded to the control chip pads 413, and the first insulating region is bonded to the second insulating region. The plurality of the memory chip pads 412 are connected to metal layers 407 in the memory chip 431 by a plurality of vias, which are the memory chip vias 411 and a plurality of second conductive pads 413 are connected to metal layers in the control chip 432 by a plurality of second vias, which are the control chip vias 414, wherein the plurality of memory chip vias 411 comprise a same length that they do not form a staircase shape.

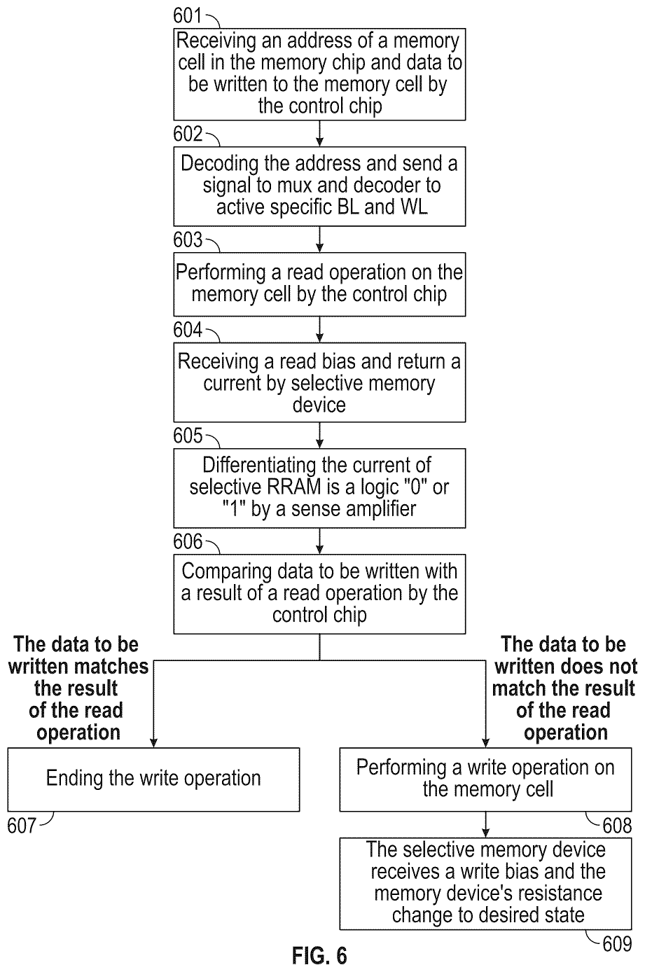

The following describes a method for performing a write operation in a memory device, as referred to FIG. 6. The method shown in FIG. 6 includes the following control flow steps:
S601: receiving an address of a memory cell in the memory chip and data to be written to the memory cell by the control chip;
S602: decoding the address and send a signal to mux and decoder to active specific BL and WL;
S603: performing a read operation on the memory cell by the control chip;
S604: receiving a read bias and return a current by selective memory device;
S605: differentiating the current of selective RRAM is a logic “0” or “1” by a sense amplifier;
S606: comparing data to be written with a result of a read operation by the control chip;
S607: if the data to be written matches the result of the read operation, ending the write operation;
S608: if the data to be written does not match the result of the read operation, performing a write operation on the memory cell;
S609: the selective memory device receives a write bias and the memory device's resistance change to desired state.

The memory device includes a memory chip comprising a plurality of memory cells made at a first process node; and a control chip comprising a control circuit made at a second process node, wherein the first process node is more advanced than the second process node; wherein the control chip and the memory chip are bonded together to form the memory device, and the control circuit is configured to control an operation of the plurality of the memory cells in the memory chip.

In S601, S602, S605, S606 and S607, a signal is sent within the same chip (either within the control chip or within the memory chip).

In S603, S604 S608 and S609, a signal is sent across the control chip and the memory chip.

Differ from prior art, where all bits are programmed regardless of the value to be stored, the present invention introduces a more efficient approach. Before a write operation, the control chip performs a read operation on the memory cell to determine whether the bit needs programming. If the stored value matches the desired data, no programming is performed. Additionally, the present invention eliminates the need for a refresh operation.

This selective write process of the present invention reduces unnecessary write cycles, which is particularly beneficial for RRAM, as it has a limited write endurance. By reducing the number of write operations, our approach extends the lifespan of both the RRAM and the entire device, enhancing durability and reliability.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. Other embodiments may have layers in different orders, additional layers or fewer layers than the illustrated embodiments.

Various operations are described as multiple discrete operations, in turn, in a manner that is most helpful in understanding the present invention, however, the order of description should not be construed to imply that these operations are necessarily order dependent. In particular, these operations need not be performed in the order of presentation.

The terms “over,” “above” “under,” “between,” and “on” as used herein refer to a relative position of one material layer or component with respect to other layers or components. For example, one layer deposited above or over or under another layer may be directly in contact with the other layer or may have one or more intervening layers. Moreover, one layer deposited between two layers may be directly in contact with the two layers or may have one or more intervening layers. In contrast, a first layer “on” a second layer is in direct contact with that second layer. Similarly, unless explicitly stated otherwise, one feature deposited between two features may be in direct contact with the adjacent features or may have one or more intervening layers.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims may generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. The terms “first,” “second,” “third,” “fourth,” etc. as used herein are meant as labels to distinguish among different elements and may not necessarily have an ordinal meaning according to their numerical designation.

What is claimed is:

1. A memory device, comprising:
a memory chip comprising a plurality of memory cells made at a first process node; and
a control chip comprising a control circuit made at a second process node, wherein the first process node is more advanced than the second process node;
wherein the control chip and the memory chip are bonded together to form the memory device, and the control circuit is configured to control an operation of the plurality of the memory cells in the memory chip.

2. The memory device of claim 1, wherein the control circuit further comprises a multiplexer configured to control a source line or a bit line for a memory cell.

3. The memory device of claim 2, wherein the memory chip does not comprise a multiplexer configured to control a source line or a bit line for a memory cell.

4. The memory device of claim 1, wherein the control circuit further comprises a decoder configured to control a word line for a memory cell.

5. The memory device of claim 4, wherein the memory chip does not comprise a decoder configured to control a word line for a memory cell.

6. The memory device of claim 1, wherein the control circuit further comprises a sense amplifier configured to amplify a signal from a memory cell.

7. The memory device of claim 1, wherein the control circuit further comprises a charge pump configured to generate voltage required to program a memory cell.

8. The memory device of claim 1, wherein the control chip further comprises a processor.

9. The memory device of claim 1, wherein the control chip further comprises an analog circuit.

10. The memory device of claim 1, wherein the control chip further comprises a transmitter.

11. The memory device of claim 1, wherein the control chip further comprises a sensor.

12. The memory device of claim 1, wherein a gate length of a transistor in the memory chip is smaller than a gate length of a transistor in the control chip.

13. The memory device of claim 1, wherein the memory chip comprises only one type of transistors, and the control chip comprises a plurality type of transistors.

14. The memory device of claim 13, wherein the memory chip comprises only NMOS transistors.

15. The memory device of claim 13, wherein the memory chip comprises only PMOS transistors.

16. The memory device of claim 1, wherein each memory cell comprises a memory element formed above a substrate.

17. The memory device of claim 16, wherein the memory element is selected from a group consisting of:
a Resistive Random Access Memory (RRAM);
a Conductive-Bridge Random Access Memory (CBRAM);
a Magnetic Random Access Memory (MRAM);
a Ferroelectric Random Access Memory (FeRAM); and
a Phase Change Random Access Memory (PCRAM).f

18. The memory device of claim 1, wherein each memory cell comprises a resistive memory element formed above a substrate.

19. The memory device of claim 18, wherein the memory cell comprises:
an access transistor formed on the substrate;
a contact;
a first metal layer;
a bottom electrode;
the resistive memory element;
a first via; and
a second metal layer;
wherein the contact is disposed between a terminal of the access transistor and the first metal layer, the bottom electrode is disposed between the first metal layer and the resistive memory element, the first via is disposed between the resistive memory element and the second metal layer.

20. The memory device of claim 18, wherein a top surface of the memory chip comprises a plurality of first conductive pads and a first insulating region, a top surface of the control chip comprises a plurality of second conductive pads and a second insulating region.

21. The memory device of claim 20, wherein a first conductive pad is bonded to a second conductive pad, and the first insulating region is bonded to the second insulating region.

22. The memory device of claim 20, wherein the plurality of first conductive pads are connected to a second metal layer in the memory chip by a plurality of memory chip vias, and a plurality of second conductive pads are connected to a second metal layer in the control chip by a plurality of control chip vias, wherein the plurality of memory chip vias comprise a same length.

23. The memory device of claim 1, wherein, prior to performing a write operation to a memory cell, the control circuit is configured to perform a read operation on the memory cell.

24. The memory device of claim 23, wherein, prior to performing a write operation to a memory cell, the control circuit is configured to compare data to be written with a result of a read operation.

25. The memory device of claim 23, wherein the control circuit is configured to perform the write operation only if the data to be written does not match the result of the read operation.

26. A method for performing a write operation in a memory device, wherein the memory device comprises
a memory chip comprising a plurality of memory cells made at a first process node; and
a control chip comprising a control circuit made at a second, wherein the first process node is more advanced than the second process node;
wherein the control chip and the memory chip are bonded together to form the memory device, and the control circuit is configured to control an operation of the plurality of the memory cells in the memory chip;
the method comprising:
receiving an address of a memory cell in the memory chip and data to be written to the memory cell by the control chip;
performing a read operation on the memory cell; and
performing a write operation on the memory cell after the read operation.

27. The method of claim 26, further comprising:
comparing the data to be written with a result of the read operation before performing the write operation on the memory cell.

28. The method of claim 27, wherein performing a write operation on the memory cell after the read operation comprising performing a writing operation on the memory cell after the read operation only if the data to be written does not match the result of the read operation.
